(19) United States
(12) Patent Application Publication
(10) Pub. No.: US 2019/0088681 A1
(43) Pub. Date: Mar. 21, 2019

(54) ARRAY SUBSTRATE, METHOD FOR MANUFACTURING THE SAME, AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventor: Suzhen MU, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/512,508

(22) PCT Filed: Aug. 15, 2016
(86) PCT No.: PCT/CN2016/095290

§ 371 Date: Mar. 17, 2017

(30) Foreign Application Priority Data
Mar. 7, 2016 (CN) 201610129930.6

(51) Int. Cl. H01L 27/12

(52) U.S. Cl. CPC H01L 27/124; H01L 27/1262

(57) ABSTRACT

An array substrate, a method for manufacturing the array substrate, and a display device are provided. The array substrate includes a base, and a common electrode trace pattern and a connection portion pattern arranged on the base. The common electrode trace pattern is arranged in the same layer as the data line pattern, and includes a plurality of sets of row common electrode traces, each set of the row common electrode traces is arranged between two adjacent rows of pixels and is connected by connection portions in the connection portion pattern, each row common electrode trace is located in an idle region between two adjacent data lines, and the idle region is aligned with thin film transistors between two adjacent rows of pixels in a column direction.

### CROSS-REFERENCE TO RELATED APPLICATIONS

The present application claims a priority of a Chinese patent application No. 201610129930.6 filed in China on Mar. 7, 2016, contents of which are incorporated herein by reference in its entirety.

### TECHNICAL FIELD

The present disclosure relates to a field of display techniques, and in particular to an array substrate, a method for manufacturing the array substrate, and a display device.

### BACKGROUND

In order to achieve polarity reversal or reduce the number of data driving circuits, a design of a Dual Gate structure is proposed in the related art. In an array substrate including the Dual Gate structure, two gate lines are arranged between two adjacent rows of pixels, one of the two gate lines adjacent to a previous row of the two adjacent rows of pixels is connected with the previous row of pixels, and the other of the two gate lines adjacent to a next row of the two rows of pixels is connected with the next row of pixels.

In another aspect, in order to improve uniformity of a common voltage on a common electrode, a common electrode trace is arranged in a non-opening region between the two adjacent rows of pixels in the related art. The common electrode trace is usually made of a metal having a lower resistivity, and is connected with the common electrode through a plurality of via-holes and supplies the common voltage to the common electrode, so as to ensure the uniformity of the common voltage on the common electrode.

On a basis of the design of the Dual Gate structure, if another common electrode trace is provided, three independent metal lines need to be formed between the two adjacent rows of pixels. To avoid an influence of metal lines used as the common electrode traces on a connection between a gate line and a thin film transistor, the common electrode traces need generally to be arranged between two metal lines used as gate lines. Such arrangement may substantially reduce an aperture ratio of pixels.

### SUMMARY

An object of the present disclosure is to improve an aperture ratio of pixels.

A first aspect of the present disclosure provides an array substrate, wherein the array substrate includes a base; and a common electrode layer, an array of thin film transistors, a pixel electrode pattern, a data line pattern, a gate line pattern, a common electrode trace pattern, and a connection portion pattern that are arranged on the base.

A gate line set is arranged between each pair of two adjacent rows of pixels, each gate line set includes two gate lines, and two columns of pixels are arranged between two adjacent data lines; each data line is connected with two thin film transistors at a location where the data line overlaps with each gate line set, and each of the two thin film transistors is correspondingly connected with one of the two gate lines of the gate line set; the common electrode trace pattern is arranged in the same layer as the data line pattern, and comprises a plurality of sets of row common electrode traces, each set of row common electrode traces is arranged between two adjacent rows of pixels, each row common electrode trace in each set of row common electrode traces is located in an idle region between the two adjacent data lines, and the idle region is aligned with thin film transistors between the two adjacent rows of pixels in a column direction.

The connection portion pattern includes a plurality of connection portions, each of the plurality of connection portions is arranged at a location where each data line overlaps with each gate line set, and layered structures between ends of each row common electrode trace and connection portions adjacent the ends in a row direction are provided with via-holes, each connection portion connects two adjacent row common electrode traces together through the via-holes; and a layered structure between each row common electrode trace and the common electrode layer is provided with a via-hole at a location of the row common electrode trace, and the row common electrode trace is connected with the common electrode layer through the via hole.

Further, the common electrode trace pattern further includes a plurality of column common electrode traces, each of the plurality of column common electrode traces is correspondingly arranged between two adjacent columns of pixels located between two adjacent data lines, and each row common electrode trace is connected with one of the plurality of column common electrode traces.

Further, the common electrode trace pattern further includes a plurality of sets of row auxiliary common electrode traces in the row direction; and each set of the row auxiliary common electrode traces is located at folding positions of a row of pixel electrodes in the column direction, each auxiliary common electrode trace in each set of the row auxiliary common electrode traces is located between two adjacent data lines and is connected to one of the plurality of column common electrode traces.

Further, in the two thin film transistors to which each data line is connected at the location where the data line overlaps with each gate line set, each of the two thin film transistors is correspondingly connected to one of the two gate lines of the gate line set and is located at a side of the connected gate line away from the other gate line of the gate line set, and is also connected to a pixel electrode in a row of pixels located at the side of the connected gate line away from the other gate line; in a plurality of pairs of thin film transistors to which data lines are connected at locations where the data lines overlap with the same gate line set, a first thin film transistor in each pair of thin film transistors is located at a first side of the gate line set, and a second thin film transistor in the pair of thin film transistors is located at a second side of the gate line set; in four thin film transistors to which the same data line is connected at locations where the same data line overlaps with two adjacent gate line sets in the column direction, one first thin film transistor is located at a first side of one of the two gate line sets corresponding to the one first thin film transistor, the other first thin film transistor is located at a second side of the other of the two gate line sets corresponding to the other first thin film transistor, and one second thin film transistor is located at the second side of the one of the two gate line sets corresponding to the one second thin film transistor, and the other second thin film transistor is located at the first side of the other of the two gate line sets corresponding to the other second thin film transistor; and a position of a first end of each row common electrode trace in the column direction coincides with the first thin film transistor to which a data line adjacent to the first end is connected, and a position of a second end of the row common electrode trace in the column direction coincides with the second thin film transistor to which a data line adjacent to the second end is connected.

Further, the connection portion pattern and the pixel electrode pattern are arranged in the same layer.

Further, the common electrode layer is arranged on the base; and the array of thin film transistors, the data line pattern, the gate line pattern, the common electrode trace pattern and the connection portion pattern are arranged on the common electrode layer.

Further, the first thin film transistor is a thin film transistor located on a left side of one of the data lines corresponding to the first thin film transistor, and the second thin film transistor is a thin film transistor located on a right side of one of the data lines corresponding to the second thin film transistor.

A second aspect of the present disclosure provides a method for manufacturing an array substrate, including: forming a common electrode layer, an array of thin film transistors, a pixel electrode pattern, a data line pattern, a gate line pattern, a common electrode trace pattern and a connection portion pattern on a base; wherein a gate line set is arranged between each pair of two adjacent rows of pixels, each gate line set includes two gate lines, and two columns of pixels are arranged between two adjacent data lines; each data line is connected with two thin film transistors at a location where the data line overlaps with each gate line set, and one of the two thin film transistors is correspondingly connected with one of the two gate lines of the gate line set.

The common electrode trace pattern is adapted to be formed in the same process for forming the data line pattern and includes a plurality of sets of row common electrode traces, each set of the row common electrode traces of the plurality of sets of row common electrode traces is arranged between two adjacent rows of pixels, each row common electrode trace in each set of row common electrode traces is located in an idle region between two adjacent data lines, and the idle region is aligned with thin film transistors between the two adjacent rows of pixels in a column direction.

The connection portion pattern includes a plurality of connection portions, each of the plurality of connection portions is arranged at a location where each data line overlaps with each gate line set, and layered structures between ends of each row common electrode trace and connection portions adjacent the ends in a row direction are provided with via-holes, and each connection portion connects two adjacent row common electrode traces together through the via-holes.

A layered structure between each row common electrode trace and the common electrode layer is provided with a via-hole at a location of the row common electrode trace, and the row common electrode trace is connected to the common electrode layer through the via-hole.

Further, the common electrode trace pattern is formed in the same process for forming the data line pattern.

Further, the connection portion pattern is formed in the same process for forming the pixel electrode pattern.

A third aspect of the present disclosure provides a display device, including the array substrate described in the first aspect.

In the array substrate provided by the present disclosure, the common electrode trace pattern is arranged in the same layer as the data line pattern, the common electrode trace pattern in one row is divided into a plurality of common electrode traces, and each common electrode trace is arranged between two adjacent data lines of a plurality of data lines and is connected to an adjacent common electrode trace by the connection portion pattern at a location of each data line, and is arranged in the idle region that is aligned with thin film transistors between two adjacent rows of pixels in the column direction. Compared to a manner of the related art in which one common electrode trace is specially provided between two gate lines, an area of the non-opening region of the array substrate provided by the present disclosure may be reduced, thereby improving the aperture ratio of pixels.

### BRIEF DESCRIPTION OF THE DRAWINGS

Features and advantages of the present disclosure will be more apparent with reference to the accompanying drawings. These drawings are schematic illustrations only and should not be construed as limiting the present disclosure in any way.

FIG. 1 is a structural schematic diagram of an array substrate according to some embodiments of the present disclosure; and

FIG. 2 is a structural schematic diagram of an array substrate according to some embodiments of the present disclosure.

### DETAILED DESCRIPTION

In order to make the above objects, features and advantages of the present disclosure more apparent, the present disclosure will be described in details hereinafter in conjunction with the drawings and embodiments. It should be noted that, the embodiments of the present disclosure and features of the embodiments may be combined with each other on condition that no conflict may be caused.

Numerous specific details are set forth in the following description, to provide a thorough understanding of the present disclosure. However, the present disclosure may be implemented in other manners different from those described in the present disclosure. Therefore, the protection scope of the present disclosure is not limited to the specific embodiments disclosed hereinafter.

A first aspect of the present disclosure provides an array substrate 1. The array substrate 1 includes: a base; and a common electrode layer, an array of thin film transistors, a pixel electrode pattern, a data line pattern, a gate line pattern, a common electrode trace pattern and a connection portion pattern which are arranged on the base. A gate line set is arranged between each pair of two adjacent rows of pixels, each gate line set includes two gate lines, and two columns of pixels are arranged between two adjacent data lines.

Each data line is connected with two thin film transistors at a location where the data line overlaps with each gate line set, and each of the two thin film transistors is correspondingly connected with one of the two gate lines in this gate line set.

The common electrode trace pattern is arranged in the same layer as the data line pattern, and includes a plurality of sets of row common electrode traces arranged in a row direction, wherein each set of row common electrode traces is arranged between two adjacent rows of pixels, and each row common electrode trace in each set of row common electrode trace is located in an idle region between two adjacent data lines, and the idle region is aligned with thin film transistors between two adjacent rows of pixels in a column direction.

The connection portion pattern includes a plurality of connection portions, each of the plurality of connection portions is arranged at the location where each data line overlaps with each gate line set, and layered structures between ends of each row common electrode trace and connection portions adjacent to the ends are provided with via-holes, and each connection portion connects two row common electrode traces adjacent in the row direction together through the via-holes.

A layered structure between each row common electrode trace and the common electrode layer is arranged with a via-hole at a location of the row common electrode trace, and the row common electrode trace is connected with the common electrode layer through the via hole.

In the array substrate 1 provided by the embodiments of the present disclosure, the common electrode trace pattern is arranged in the same layer as the data line pattern. The common electrode trace pattern in the same row is divided into a plurality of common electrode traces. Each common electrode trace is arranged between two adjacent data lines of a plurality of data lines, and is connected to another common electrode trace by a connection portion pattern at the location of each data line, and is arranged in the idle region that is aligned with thin film transistors between two adjacent rows of pixels in the column direction.

The array substrate 1 is described in details in combination with the accompanying drawings.

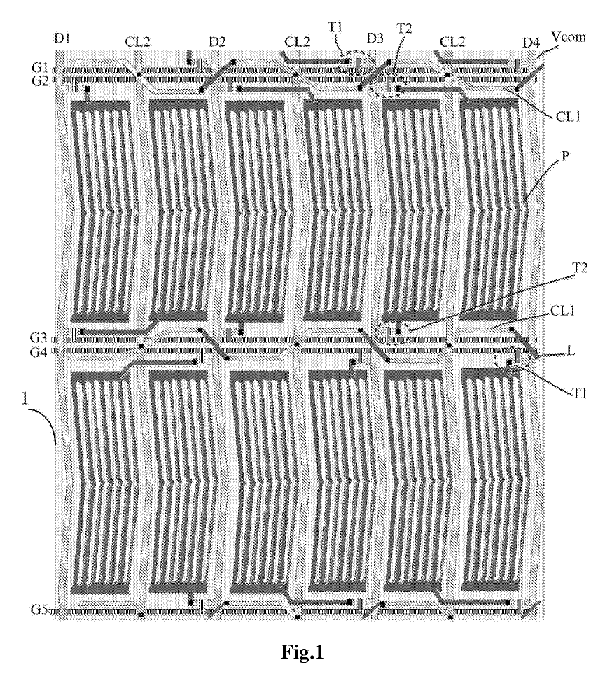

A top view of a structure of the array substrate 1 provided by the embodiments of the present disclosure is shown in FIG. 1. Referring to FIG. 1, the array substrate 1 includes: a base; a common electrode layer arranged on the base; and an array of thin film transistors, a pixel electrode pattern, a data line pattern, a gate line pattern, a common electrode trace pattern and a connection portion pattern formed on the common electrode layer, wherein the date line pattern includes a plurality of data lines. For convenience, data lines in FIG. 1 are denoted as D1, D2, D3 and D4 sequentially from the left to the right. The gate line pattern includes a plurality of gate lines. For convenience, gate lines in FIG. 1 are denoted as G1, G2, G3, G4 and G5 sequentially from top to bottom. The array of thin film transistors includes a plurality of thin film transistors. For convenience, a thin film transistor located at a left side of a data line connected thereto is denoted as T1, and a thin film transistor located at a right side of the data line connected thereto is denoted as T2. The pixel electrode pattern includes a plurality of pixel electrodes. For convenience, each of the plurality of pixel electrodes is denoted as P. The connection portion pattern and the pixel electrode pattern are arranged in the same layer and may be made of the same material. Thus, the connection portion pattern and the pixel electrode pattern are shown in FIG. 1 by the same pattern. Specifically, the connection portion pattern includes a plurality of connection portions. Each connection portion is denoted as L in FIG. 1. For convenience, the common electrode layer is denoted as Vcom in FIG. 1. The common electrode trace pattern and the common electrode layer may be made of the same material, and thus are also shown by the same pattern in FIG. 1. Specifically, the common electrode trace pattern includes a plurality of row common electrode traces arranged in a row direction and a plurality of column common electrode traces arranged in a column direction. For convenience, the row common electrode traces are denoted as CL1, and the column common electrode traces are denoted as CL2.

Referring to FIG. 1, a gate line set is arranged between each pair of two adjacent rows of pixels, and each gate line set includes two gate lines. For example, the gate lines G3 and G4 constitute one gate line set arranged between two adjacent rows of pixels. Two columns of pixels are arranged between two adjacent data lines, e.g., D1 and D2 shown in FIG. 1.

Each data line is connected with two thin film transistors T1 and T2 at a location where each data line overlaps with each gate line set, and each of the two thin film transistors T1 and T2 is correspondingly connected with one of the two gate lines in the gate line set.

The common electrode trace pattern and the data line pattern are arranged in the same layer. The plurality of row common electrode traces CL1 included in the common electrode trace pattern are divided into a plurality of sets. Each set of row common electrode traces CL1 is arranged between each pair of two adjacent rows of pixels. Each row common electrode trace CL1 in each set of row common electrode traces is located in an idle region between two adjacent data lines, and the idle region means a region aligned with thin film transistors between the two adjacent rows of pixels in the column direction.

Each connection portion L is arranged at a location where each data line overlaps with each gate line set. Layered structures (the layered structures usually include insulation layers such as a gate insulation layer, an etch barrier, etc., and specific structures of the layered structures may be found in structures of array substrates in the related art) between ends of each row common electrode trace CL1 and connection portions L adjacent to the ends are provided with via-holes (the via-holes in the figure are shown by black solid-dots). Each connection portion L connects two row common electrode traces CL1 located at both sides of the same data line together through the via-holes.

A layered structure between each row common electrode trace CL1 and the common electrode layer Vcom is provided with a via-hole at a location of the row common electrode trace CL1. Each row common electrode trace CL1 is connected with the common electrode layer Vcom through the via-hole.

Each column common electrode trace CL2 is correspondingly arranged between two adjacent columns of pixels located between two adjacent data lines, and each row common electrode trace CL1 is connected with a column common electrode trace CL2 through the via-hole.

In two thin film transistors to which each data line is connected at a location where the data line overlaps with each gate line set, each thin film transistor is correspondingly connected with one of the two gate lines in the gate line set and is located at a side of the connected gate line away from the other gate line, and is also connected with a pixel electrode in one row of the two adjacent rows of pixels located at a side of the connected gate line away from the other gate line. For example, in two thin film transistors T1 and T2 connected with the data line D3 at a location where the data line D3 overlaps with a gate line set including the gate line G3 and the gate line G4, the thin film transistor T1 located at the left side is located at a side of the connected gate line G4 away from the gate line G3, and the thin film transistor T2 located at the right side is located at a side of the connected gate line G3 away from the gate line G4.

More specifically, in various thin film transistors to which data lines are connected at locations where the data lines overlap with the same gate line set, the first thin film transistors T1 are all located at the same side of the gate line set, and the second thin film transistors T2 are all located at the other side of the gate line set. For example, in the two thin film transistors T1 and T2 to which each of the data lines D1, D2, D3 and D4 is connected at a location where the data line overlaps with the gate line set including the gate line G1 and the gate line G2, the first thin film transistor T1 is located above the gate line set, and the second thin film transistor T2 is located below the gate line set.

Moreover, in four thin film transistors to which the same data line is connected at locations where the data line overlaps with two adjacent gate line sets in the column direction, one first thin film transistor T1 is above one gate line set corresponding to the one first thin film transistor T1, the other first thin film transistor T1 is below the other gate line set corresponding to the other first thin film transistor T1; and one second thin film transistor T2 is below the one gate line set corresponding to the one second thin film transistor T2, and the other second thin film transistor T2 is above the other gate line set corresponding to the other second thin film transistor T2. For example, in the two thin film transistors to which the data line D3 is connected at a location where the data line D3 overlaps with the gate line set including the gate line G1 and the gate line G2, the first thin film transistor T1 is above the gate line set including the gate line G1 and the gate line G2, and the second thin film transistor T2 is below the gate line set including the gate line G1 and the gate line G2; and in the two thin film transistors to which the data line D3 is connected at a location where the data line D3 overlaps with the gate line set including the gate line G3 and the gate line G4 (the gate line set including the gate line G3 and the gate line G4 is adjacent to the gate line set including the gate line G1 and the gate line G2), the first thin film transistor T1 is below the gate line set including the gate line G3 and the gate line G4, and the second thin film transistor T2 is above the gate line set including the gate line G3 and the gate line G4.

A shape of each row common electrode trace CL1 is a fold line, and a position of a left end of the row common electrode trace CL1 in the column direction coincides with the first thin film transistor T1 to which a data line adjacent to and on the left side of the left end is connected, and a position of a right end of the row common electrode trace CL1 in the column direction coincides with the second thin film transistor T2 to which a data line adjacent to and on the right side of the right end is connected. For example, for the row common electrode trace CL1 located between the data lines D2 and D3, a position of a left end of the row common electrode trace CL1 is adjacent to the data line D2, and the position of the left end thereof in the column direction coincides with the first thin film transistor T1 to which the data line D2 is connected and which is located on the left side of the data line D2, and a position of a right end of the row common electrode trace CL1 is adjacent to the data line D3, and the position of the right end thereof in the column direction coincides with the second thin film transistor T2 to which the data line D3 is connected and which is located on the right side of the data line D3.

In the array substrate 1 provided by the embodiments of the present disclosure, the common electrode trace pattern and the data line pattern are arranged in the same layer, and the row common electrode traces CL1 are arranged in idle regions aligned with corresponding thin film transistors in the column direction. Compared to a manner in the related art that a common electrode trace is specially provided between two gate lines, an area of a non-opening region may be reduced, thereby improving an aperture ratio of pixels.

It may be readily understood that, the idle region in the embodiments of the present disclosure is defined relative to the related art, and means a region where thin film transistors, gate lines, data lines or pixel electrodes are not arranged. Specifically, in FIG. 1, the idle region means a region corresponding to each row common electrode trace.

In practice, the connection portion pattern may be arranged in the same layer as the pixel electrode pattern, and may be formed in the same process for forming the pixel electrode pattern. Correspondingly, the connection portion pattern may be made of a material used to form the pixel electrode pattern, such as ITO or the like. Of course, in practice, the connection portion pattern mentioned above may also be made of other conductive materials. A specific kind of material used to form the connection portion pattern is not limited in the present disclosure on the premise that adjacent row common electrode traces may be electrically connected by the connection portion pattern.

Meanwhile, in the embodiments of the present disclosure, the shape of each row common electrode trace CL1 is arranged to be the fold line, so that each row common electrode trace CL1 is kept away from the thin film transistors and approaches corresponding data lines as closely as possible. Thus, a length of the row common electrode trace CL1 may be increased and a length of the connection portion L may be reduced, thereby being helpful to lower an overall resistivity (the connection portion L usually has a resistivity higher than that of the common electrode trace CL1) in the row direction. Of course, in practice, arranging the shape of each row common electrode trace CL1 to be a straight line may also achieve the object of the present disclosure, and a corresponding technical solution also falls into the protection scope of the present disclosure.

It should be noted that that, although the embodiments of the present disclosure are described by an arrangement that the array of thin film transistors, the data line pattern, the gate line pattern, the common electrode trace pattern and the connection portion pattern are disposed above the common electrode layer, a positional relationship between the common electrode layer and other patterns cannot affect implementation of the present disclosure in practice. In some other types of array substrate, the common electrode layer may also be disposed above the above-mentioned other patterns.

In the embodiments of the present disclosure, a column common electrode trace CL2 is further arranged between two adjacent columns of pixels located between two adjacent data lines. The column common electrode trace CL2 and the row common electrode trace CL1 are connected to form an integral structure, so that a resistance of a common electrode transmission structure (the common electrode transmission structure includes the common electrode trace pattern and the connection portion pattern) may be further lowered when the common voltage is transmitted on the common electrode transmission structure. Of course, the column common electrode trace CL2 is not necessarily provided in practice, and the object of the present disclosure may still be achieved. It is readily understood that, arrangements of the other patterns may not be affected without the column common electrode trace CL2.

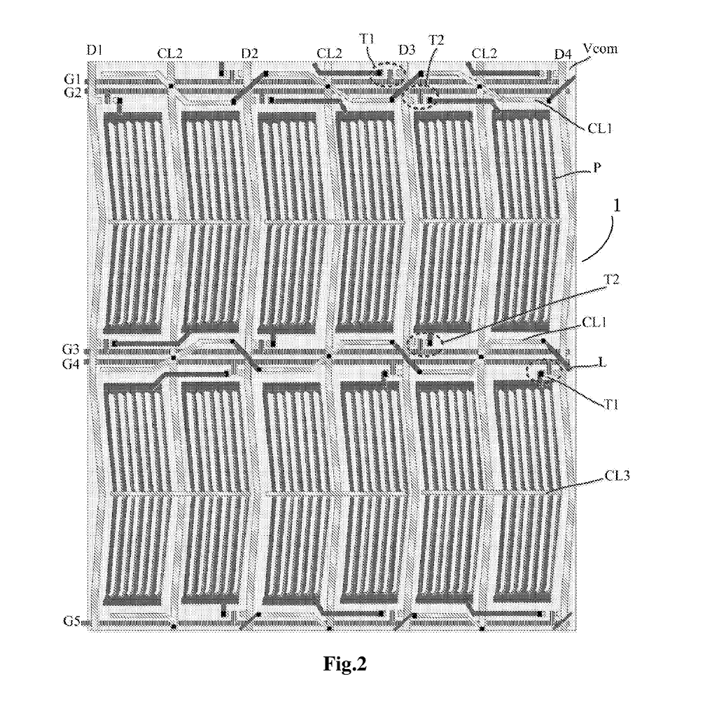

Referring to FIG. 2, another array substrate is provided in this embodiment. A difference between the array substrate in this embodiment and the array substrate in the previous embodiment is that the common electrode trace pattern further includes a plurality of sets of row auxiliary common electrode traces.

Each set of row auxiliary common electrode traces is located at folding positions of a row of pixel electrodes in the column direction, and each row auxiliary common electrode trace CL3 in each set of row auxiliary common electrode traces is located between two adjacent data lines and is connected with a column common electrode trace CL2.

In this embodiment, because the auxiliary common electrode trace CL3 is connected with the column common electrode trace CL2, the resistance of the corresponding common electrode transmission structure may be further reduced when the common voltage is transmitted in the common electrode transmission structure. In addition, because alignment of liquid crystal molecules at the folding positions of the pixel electrodes P is much or less disordered and these liquid crystal molecules generally do not participate in displaying, arranging each auxiliary common electrode trace CL3 at the folding positions of the pixel electrodes P in the embodiment of the present disclosure does not significantly affect the aperture ratio of the pixel electrodes.

A second aspect of the present disclosure provides a method for manufacturing an array substrate. The method for manufacturing an array substrate may be used to manufacture the array substrate according to the first aspect. The method may include the following step: forming a common electrode layer, an array of thin film transistors, a pixel electrode pattern, a data line pattern, a gate line pattern, a common electrode trace pattern and a connection portion pattern on a base, wherein a gate line set is arranged between each pair of two adjacent rows of pixels, each gate line set includes two gate lines, and two columns of pixels are arranged between two adjacent data lines; each data line is connected with two thin film transistors at a location where the data line overlaps with each gate line set, and each thin film transistor is correspondingly connected with one of the two gate lines of the gate line set; the common electrode trace pattern is adapted to be formed in the same process for forming the data line pattern and includes a plurality of sets of row common electrode traces, each set of the row common electrode traces is arranged between two adjacent rows of pixels, and each row common electrode trace in each set of row common electrode trace is located in an idle region between two adjacent data lines, and the idle region is aligned with thin film transistors between the two adjacent rows of pixels in a column direction; the connection portion pattern includes a plurality of connection portions, each connection portion is arranged at a location where each data line overlaps with each gate line set, and layered structures between ends of each row common electrode trace and connection portions adjacent to the ends in a row direction are provided with via-holes, each connection portion connects two adjacent row common electrode traces in the row direction together through the via-holes; and a layered structure between each row common electrode trace and the common electrode layer is provided with a via-hole at a location of the row common electrode trace, each row common electrode trace is connected with the common electrode layer through the via-hole.

The step of forming the common electrode layer, the array of thin film transistors, the pixel electrode pattern, the data line pattern and the gate line pattern on the base may be found in the related art, and thus will not be described in detail herein.

The step of forming the common electrode trace pattern may be performed in the same process for forming the data line pattern. In this way, a difficulty of manufacturing the array substrate may be reduced. The entirety of the common electrode trace pattern formed in this way is arranged in the same layer as the data line pattern.

The step of forming the connection portion pattern may be performed in the same process for forming the pixel electrode pattern. In this way, a difficulty of manufacturing the array substrate may be reduced. The entirety of the connection portion pattern formed in this way is arranged in the same layer as the data line pattern.

A third aspect of the present disclosure provides a display device including the array substrate described in the first aspect.

The display device herein may be a product having touch and display functions such as a mobile phone, a tablet, a navigator, etc.

Although the embodiments of the present disclosure are described in details in conjunction with the drawings, one skilled in the art may make various improvements and modifications without departing from the principle and scope of the present disclosure, and these improvements and modifications shall also fall within the scope of the present disclosure defined by the claims below.

1. An array substrate, comprising:
a base; and
a common electrode layer, an array of thin film transistors, a pixel electrode pattern, a data line pattern, a gate line pattern, a common electrode trace pattern, and a connection portion pattern, that are arranged on the base;
wherein a gate line set is arranged between each pair of two adjacent rows of pixels, each gate line set comprises two gate lines, and two columns of pixels are arranged between two adjacent data lines;
each data line is connected with two thin film transistors at a location where the data line overlaps with each gate line set, and each of the two thin film transistors is correspondingly connected with one of the two gate lines of the gate line set;
the common electrode trace pattern is arranged in the same layer as the data line pattern, and comprises a plurality of sets of row common electrode traces, each set of row common electrode traces is arranged between two adjacent rows of pixels, each row common electrode trace in each set of row common electrode traces is located in an idle region between the two adjacent data lines, and the idle region is aligned with thin film transistors between the two adjacent rows of pixels in a column direction;
the connection portion pattern comprises a plurality of connection portions, each of the plurality of connection portions is arranged at a location where each data line overlaps with each gate line set, and layered structures between ends of each row common electrode trace and connection portions adjacent to the ends in a row direction are provided with via-holes, each connection portion connects two adjacent row common electrode traces together through the via-holes; and
a layered structure between each row common electrode trace and the common electrode layer is provided with a via-hole at a location of the row common electrode trace, and the row common electrode trace is connected with the common electrode layer through the via hole.

2. The array substrate according to claim 1, wherein the common electrode trace pattern further comprises a plurality of column common electrode traces, each of the plurality of column common electrode traces is correspondingly arranged between two adjacent columns of pixels located between two adjacent data lines, and each row common electrode trace is connected with one of the plurality of column common electrode traces.

3. The array substrate according to claim 1, wherein the common electrode trace pattern further comprises a plurality of sets of row auxiliary common electrode traces in the row direction; and
each set of the row auxiliary common electrode traces is located at folding positions of a row of pixel electrodes in the column direction, each row auxiliary common electrode trace in each set of the row auxiliary common electrode traces is located between two adjacent data lines and is connected with one of the plurality of column common electrode traces.

4. The array substrate according to claim 1, wherein,
in the two thin film transistors to which each data line is connected at the location where the data line overlaps with each gate line set, each of the two thin film transistors is correspondingly connected with one of the two gate lines of the gate line set and is located at a side of the connected gate line away from the other gate line of the gate line set, and is also connected with a pixel electrode in a row of pixels located at the side of the connected gate line away from the other gate line;
in a plurality of pairs of thin film transistors to which data lines are connected at locations where the data lines overlap with the same gate line set, a first thin film transistor in each pair of thin film transistors is located at a first side of the gate line set, and a second thin film transistor in each pair of thin film transistors is located at a second side of the gate line set;
in four thin film transistors to which a data line is connected at locations where the data line overlaps with two adjacent gate line sets in the column direction, one first thin film transistor is located at a first side of one of the two gate line sets corresponding to the one first thin film transistor, the other first thin film transistor is located at a second side of the other of the two gate line sets corresponding to the other first thin film transistor, and one second thin film transistor is located at the second side of the one of the two gate line sets corresponding to the one second thin film transistor, and the other second thin film transistor is located at the first side of the other of the two gate line sets corresponding to the other second thin film transistor; and
a position of a first end of each row common electrode trace in the column direction coincides with the first thin film transistor to which a data line adjacent to the first end is connected, and a position of a second end of the row common electrode trace in the column direction coincides with the second thin film transistor to which a data line adjacent to the second end is connected.

5. The array substrate according to claim 1, wherein the connection portion pattern and the pixel electrode pattern are arranged in the same layer.

6. The array substrate according to claim 1, wherein the common electrode layer is arranged on the base; and the array of thin film transistors, the data line pattern, the gate line pattern, the common electrode trace pattern and the connection portion pattern are arranged on the common electrode layer.

7. The array substrate according to claim 4, wherein the first thin film transistor is a thin film transistor located on a left side of one of the data lines corresponding to the first thin film transistor, and the second thin film transistor is a thin film transistor located on a right side of the one of the data lines corresponding to the second thin film transistor.

8. A method for manufacturing an array substrate, comprising:
forming a common electrode layer, an array of thin film transistors, a pixel electrode pattern, a data line pattern, a gate line pattern, a common electrode trace pattern and a connection portion pattern on a base;
wherein a gate line set is arranged between each pair of two adjacent rows of pixels, each gate line set comprises two gate lines, and two columns of pixels are arranged between two adjacent data lines;
each data line is connected with two thin film transistors at a location where the data line overlaps with each gate line set, and one of the two thin film transistors is correspondingly connected with one of the two gate lines of the gate line set;
the common electrode trace pattern is adapted to be formed in the same process for forming the data line pattern and comprises a plurality of sets of row common electrode traces, each set of the row common electrode traces of the plurality of sets of row common electrode traces is arranged between two adjacent rows of pixels, each row common electrode trace in each set of row common electrode traces is located in an idle region between two adjacent data lines, and the idle region is aligned with thin film transistors between the two adjacent rows of pixels in a column direction;
the connection portion pattern comprises a plurality of connection portions, each of the plurality of connection portions is arranged at a location where each data line overlaps with each gate line set, and layered structures between ends of each row common electrode trace and connection portions adjacent to the ends in a row direction are provided with via-holes, and each connection portion connects two adjacent row common electrode traces together through the via-holes; and
a layered structure between each row common electrode trace and the common electrode layer is provided with a via-hole at a location of the row common electrode trace, and the row common electrode trace is connected with the common electrode layer through the via-hole.

9. The method according to claim 8, wherein the common electrode trace pattern is formed in the same process for forming the data line pattern.

10. The method according to claim 8, wherein the connection portion pattern is formed in the same process for forming the pixel electrode pattern.

11. The method according to claim 8, wherein the common electrode trace pattern further comprises a plurality of column common electrode traces, each of the plurality of column common electrode traces is correspondingly arranged between two adjacent columns of pixels located between two adjacent data lines, and each row common electrode trace is connected with one of the plurality of column common electrode traces.

12. The method according to claim 8, wherein the common electrode trace pattern further comprises a plurality of sets of row auxiliary common electrode traces in a row direction; and
each set of row auxiliary common electrode traces is located at folding positions of a row of pixel electrodes in the column direction, each auxiliary common electrode trace in each set of row auxiliary common electrode traces is located between two adjacent data lines and is connected with one of the plurality of column common electrode traces.

13. The method according to claim 8, wherein each of the two thin film transistors to which each data line is connected at the location where the data line overlaps with each gate line set, is correspondingly connected with one of the two gate lines in the gate line set and is located at a side of the connected gate line away from the other gate line in the gate line set, and is also connected with a pixel electrode in a row of pixels located at the side of the connected gate line away from the other gate line;
in a plurality of pairs of thin film transistors to which data lines are connected at locations where the data lines overlap with the same gate line set, a first thin film transistor in each pair of thin film transistors is located on a first side of the gate line set, and a second thin film transistor in the pair of thin film transistors is located on a second side of the gate line set;
in four thin film transistors to which the same data line is connected at locations where the same data line overlaps with two adjacent gate line sets in the column direction, one first thin film transistor is located on a first side of one of the two gate line sets corresponding to the one first thin film transistor, the other first thin film transistor is located on a second side of the other of the two gate line sets corresponding to the other first thin film transistor, and one second thin film transistor is located on the second side of the one of the two gate line sets corresponding to the one second thin film transistor, and the other second thin film transistor is located on the first side of the other of the two gate line sets corresponding to the other second thin film transistor; and
a position of a first end of each row common electrode trace in the column direction coincides with the first thin film transistor to which a data line adjacent to the first end is connected, and a position of a second end of the row common electrode trace in the column direction coincides with the second thin film transistor to which a data line adjacent to the second end is connected.

14. The method according to claim 13, wherein the first thin film transistor is a thin film transistor located on a left side of a data line corresponding to the first thin film transistor, and the second thin film transistor is a thin film transistor located on a right side of a data line corresponding to the second thin film transistor.

15. A display device comprising the array substrate according to claim 1.

16. A display device comprising the array substrate according to claim 2.

17. A display device comprising the array substrate according to claim 3.

18. A display device comprising the array substrate according to claim 4.

19. A display device comprising the array substrate according to claim 5.

20. A display device comprising the array substrate according to claim 6.
